(19) United States
(12) Patent Application Publication
(10) Pub. No.: US 2010/0004884 A1
(43) Pub. Date: Jan. 7, 2010

(54) SYSTEM AND METHOD FOR DETERMINING CAPACITY OF BATTERY OF ELECTRONIC DEVICE

(75) Inventor: YI-BO LIU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD, Tu- Cheng (TW)

(21) Appl. No.: 12/272,918

(22) Filed: Nov. 18, 2008

(30) Foreign Application Priority Data
Jul. 1, 2008 (CN) 200810302481.6

(51) Int. Cl. G01R 31/36

(52) U.S. Cl. 702/63

(57) ABSTRACT

A capacity determining system includes a measuring module, a reference module, and a calculating module. The measuring module is configured to measure current capacity of a battery of an electronic device. The reference module is configured to define standard consuming capacities of functions of the electronic device. The calculating module is configured to calculate results for performing the functions by respectively dividing the standard consuming capacities into the current capacity. A method for determining capacity of a battery of an electronic device is also provided.

### BACKGROUND

1. Technical Field

The present disclosure relates to a system and a method for determining a capacity of a battery of an electronic device.

2. Description of the Related Art

An electronic device such as a portable personal computer, a portable telephone, a digital camera, or other portable devices generally use a rechargeable battery to provide power to the device. Typically, a percentage of power remaining in the battery is determined by comparing a current capacity with the total capacity of the battery. However, the percentage does not accurately represent how many operations or how much time the current capacity of the battery will allow the electronic device to perform the operations, such as, for example, how many photos the electronic device can take, or how much time the electronic device can play music or movies before the supplied power is insufficient.

Therefore, there is room for improvement within the art.

### BRIEF DESCRIPTION OF THE DRAWINGS

FIG. 1 is a block diagram of an embodiment of a system for displaying a capacity of an electronic device.

FIG. 2 is a flow chart of a method for using the system of FIG. 1 to display the capacity of the electronic device.

### DETAILED DESCRIPTION OF THE EMBODIMENTS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

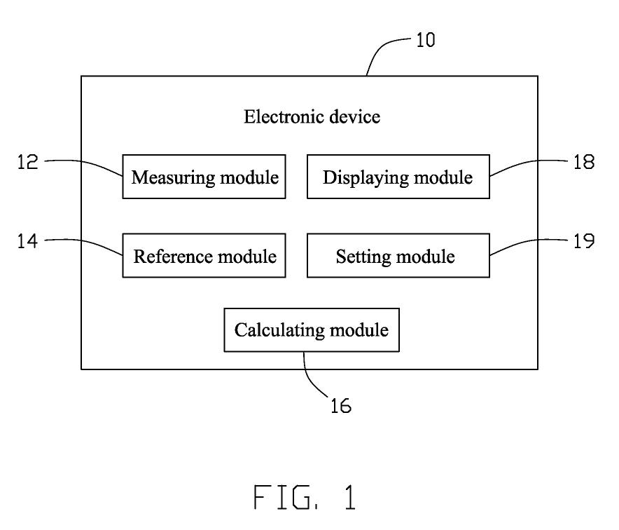

Referring to FIG. 1, an embodiment of a capacity displaying system to display a current capacity of a rechargeable battery of an electronic device 10 is shown. The electronic device 10 may be a portable telephone, a digital camera, a portable personal computer, or other device using a rechargeable battery. The capacity displaying system includes a measuring module 12, a reference module 14, a calculating module 16, a displaying module 18, and a setting module 19.

The measuring module 12 is configured to measure the current capacity P0 of the battery of the electronic device 10.

The reference module 14 is configured to define a standard consuming capacity P1 for functions of the electronic device 10. For example, the electronic device 10 having the functions that can make telephone calls, play music or movies, and take photos, would have a corresponding standard consuming capacity P1 for each function. There may be more than one method for defining the standard consuming capacity P1. In one method, a reference consuming capacity defined as the current battery capacity expended when the electronic device 10 has been used for a predetermined period of time. For example, the electronic device 10 is used to make a phone, and play music or movies in the predetermined period of time. The standard consuming capacity P1 can be calculated with the following formula (1):

P1=P2/T (1),

where P2 is the reference consuming capacity and T is the period time. In another method, a reference consuming capacity defined as the current battery capacity expended when the electronic device 10 has been normally used for a predetermined number of operations. For example, the electronic device 10 is used to take fifty photos. The standard consuming capacity P1 can be calculated according to formula (2):

P1=P2/N (2),

where P2 is the reference consuming capacity and N is the number of operations.

The calculating module 14 is configured to calculate how much remaining time T′ or how many remaining number of operations N′ of each function the electronic device 10 can perform based on the current capacity P0. The time T′ or the number of operations N′ can be calculated according to the formulas (3) and (4) respectively:

T′=P0/P1=P0/(P2/T) (3)

N′=P2/P1=P0/(P2/N) (4).

The displaying module 18 is used to show the remaining time T′ or the remaining number of operations N′ on the electronic device 10.

The setting module 19 is configured to set modes and functions within the displaying module 18 displaying the remaining time T′ or the remaining number of operations N′ on the electronic device 10. In one embodiment, there are two selectable modes to show the remaining time T′ or the remaining number of operations N′ of the electronic device 10. In the first mode, either the remaining time T′ or the remaining number of operations N′ is directly shown on the electronic device 10 as soon as the calculating module 16 calculates the result. In the second mode, either the remaining time T′ or the remaining number of operations N′ is shown on the electronic device 10 only when special instructions have been executed in the electronic device 10. In one embodiment, the number of functions shown on the electronic device 10 is configured via the setting module 19.

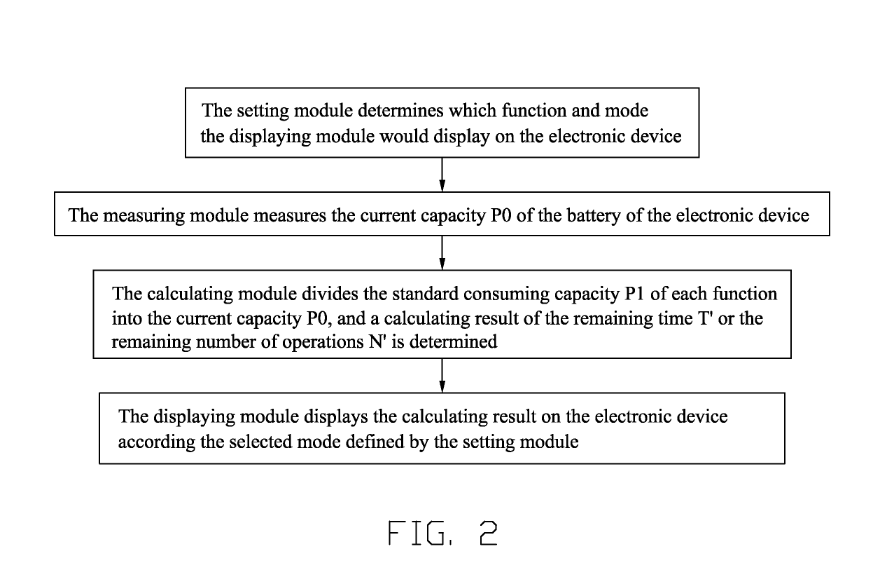

Referring also to FIG. 2, a method of determining the battery capacity of an electronic device 10 is shown. Depending on the embodiment, certain of the steps described below may be removed, others may be added, and the sequence of steps may be altered. The setting module 19 determines which function and mode of the displaying module 18 would display on the electronic device 10. The measuring module 12 measures the current capacity P0 of the battery of the electronic device 10. The calculating module 16 divides the standard consuming capacity P1 of each function set by the setting module into the current capacity P0, and a calculating result of the remaining time T′ or the remaining number of operations N′ is determined. Then, the displaying module 18 displays the calculating result of the remaining time T′ or the remaining number of operations N′ of the electronic device 10 according to the selected mode defined by the setting module 19.

It is to be understood, however, that even though numerous characteristics and advantages have been set forth in the foregoing description of embodiments, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A capacity determining system, comprising:
a measuring module configured to measure current capacity of a battery of an electronic device;
a reference module configured to define standard consuming capacities of functions of the electronic device; and
a calculating module configured to calculate results for performing the functions by respectively dividing the standard consuming capacities into the current capacity.

2. The system of claim 1, further comprising a displaying module capable of displaying the results on the electronic device.

3. The system of claim 2, further comprising a setting module capable of setting how the displaying module displays the results of the functions on the electronic device.

4. The system of claim 3, wherein the results of the functions are directly shown on the electronic device by the displaying module when the calculating module calculates the results.

5. The system of claim 3, wherein the results are shown on the electronic device only when the displaying module is instructed.

6. The system of claim 3, wherein the setting module defines which result of the functions the displaying module displays on the electronic device.

7. The system of claim 1, wherein each of the standard consuming capacities of the electronic device is determined by performing each of the functions.

8. The system of claim 1, wherein each of the standard consuming capacities is determined by dividing a predetermined period of time into a reference consuming capacity, where the reference consuming capacity is the current capacity expended performing each of the functions set by the setting module within the predetermined period of time.

9. The system of claim 6, wherein each of the standard consuming capacities is determined by dividing a predetermined number of operations into a reference consuming capacity, where the reference consuming capacity is the current capacity expended while the electronic device is performing each of the functions in the predetermined number of operations.

10. A method for determining capacity of a battery of an electronic device, the method comprising:
measuring a current capacity of the electronic device; and
calculating results for performing functions of the electronic device by dividing standard consuming capacities of performing the functions into the current capacity.

11. The method of claim 10, further comprising displaying the results of the functions on the electronic device.

12. The method of claim 11, further comprising setting how to display the results the functions on the electronic device.

13. The method of claim 12, wherein the results of the functions are directly displayed on the electronic device when the results are calculated.

14. The method of claim 12, wherein the results of the functions are displayed on the electronic device when instructed.

15. The method of claim 10, wherein each of the standard consuming capacities is determined by dividing a predetermined period of time into a reference consuming capacity, where the reference consuming capacity is the current capacity expended performing each of the functions within the predetermined period of time.

16. The method of claim 10, wherein each of the standard consuming capacities is determined by dividing the predetermined number of operations into the reference consuming capacity, where the reference consuming capacity is the current capacity expended while the electronic device is performing each of the functions in the predetermined number of operations.
